(19) United States
(12) Patent Application Publication
(10) Pub. No.: US 2011/0090649 A1
(43) Pub. Date: Apr. 21, 2011

(54) TILT-TYPE HEAT-DISSIPATING MODULE FOR INCREASING HEAT-DISSIPATING EFFICIENCY AND DECREASING LENGTH OF SOLDER PIN

(75) Inventors: Chun-Kong Chan, Hsin Chuang City (TW); Chi-Ching Chen, Hsin Chuang City (TW)

(73) Assignee: LIEN CHANG ELECTRONIC ENTERPRISE CO., LTD.

(21) Appl. No.: 12/580,677

(22) Filed: Oct. 16, 2009

(51) Int. Cl. H05K 7/20

(52) U.S. Cl. 361/709

(57) ABSTRACT

A tilt-type heat-dissipating module for increasing heat-dissipating efficiency and decreasing length of solder pin is disposed on a circuit substrate. The tilt-type heat-dissipating module includes a substrate unit, a heat-dissipating unit and an electronic unit. The substrate unit has a heat-dissipating body disposed on the circuit substrate, and one part of a top surface of the heat-dissipating body is a first inclined plane. The heat-dissipating unit has a plurality of heat-dissipating fins connected to the heat-dissipating body. The electronic unit has a plurality of electronic elements disposed on the first inclined plane of the heat-dissipating body. Each electronic element has a plurality of pins bent downwards from a bottom thereof in order to electrically connect to the circuit substrate, and heat generated by the electronic elements is transmitted to external environment by matching the heat-dissipating body and the heat-dissipating fins.

### BACKGROUND OF THE INVENTION

1. Field of the Invention

The present invention relates to a heat-dissipating module, in particular, to a tilt-type heat-dissipating module for increasing heat-dissipating efficiency and decreasing length of solder pin.

2. Description of Related Art

A computer circuit board typically has one or more heat-generating electronic devices fixed thereon. The circuit board is often installed in a cramped location inside a computer enclosure. In this environment, there is not enough space to install a conventional bulky heat sink onto any electronic device.

To reduce temperature a thermal plate can be attached onto a surface of the electronic device. The low profile of the thermal plate allows it to be accommodated in the limited space inside the computer enclosure. When there is more than one heat-generating electronic device, a single thermal plate attached to all the electronic devices is most convenient. The electronic devices generally have varying heights. Therefore a configuration of the thermal plate must be tailored to the electronic devices of a particular application to ensure that the thermal plate fits all the electronic devices well. This requires unduly high precision machining, is time consuming, and costly. In addition, a single thermal plate may not provide sufficient heat dissipation in certain applications; for example when the electronic devices generate copious amounts of heat, or when the overall configuration of the circuit board limits the coverage of the thermal plate. A second thermal plate may be attached to an opposite side of the circuit board, but establishing thermal connection between the electronic devices and the second thermal plate is problematic.

Referring to FIG. 1, the prior art provides a heat-dissipating module applied to PCB, and the heat-dissipating module includes a heat-dissipating body 10 and a heat sink 20 disposed on a top surface 100 of the heat-dissipating body 10. However, the heat-dissipating efficiency of the heat-dissipating module of the prior art is still too small, so that heat generated by electronic elements 30 cannot be quickly removed. In addition, the top surface 100 of the heat-dissipating body 10 is a plane, so that each electronic element 30 needs to design a pin 300 with enough length in order to electrically connect to a printed circuit board (PCB) P. Hence, when the heat-dissipating module is applied to the PCB P, the length of the pin 300 of the prior art cannot be reduced. In addition, the heat-dissipating module is screwed on the PCB P by using a plurality of screws S, so that the assembly time of the heat-dissipating module is increased.

### SUMMARY OF THE INVENTION

In view of the aforementioned issues, the present invention provides a tilt-type heat-dissipating module for increasing heat-dissipating efficiency and decreasing length of solder pin. The present invention can increase heat-dissipating efficiency and decrease length of solder pin by using deigns of a heat-dissipating substrate having at least one inclined plane and a plurality of heat-dissipating fins on the heat-dissipating substrate.

To achieve the above-mentioned objectives, the present invention provides a tilt-type heat-dissipating module for increasing heat-dissipating efficiency and decreasing length of solder pin disposed on a circuit substrate. The tilt-type heat-dissipating module includes a substrate unit, a heat-dissipating unit and an electronic unit. The substrate unit has a heat-dissipating body disposed on the circuit substrate, and one part of a top surface of the heat-dissipating body is a first inclined plane. The heat-dissipating unit has a plurality of heat-dissipating fins connected to the heat-dissipating body. The electronic unit has a plurality of electronic elements disposed on the first inclined plane of the heat-dissipating body. Each electronic element has a plurality of pins bent downwards from a bottom thereof in order to electrically connect to the circuit substrate, and heat generated by the electronic elements is transmitted to the external environment by matching the heat-dissipating body and the heat-dissipating fins.

To achieve the above-mentioned objectives, the present invention provides a tilt-type heat-dissipating module for increasing heat-dissipating efficiency and decreasing length of solder pin, including: a substrate unit, a heat-dissipating unit and an electronic unit. The substrate unit has a hollow heat-dissipating body, and the heat-dissipating body has a receiving space formed therein, an inclined plane formed on one part of a top surface thereof and a plane formed on another part of the top surface thereof. The heat-dissipating unit has a plurality of heat-dissipating fins disposed on the plane of the heat-dissipating body. The electronic unit has a plurality of electronic elements disposed on the inclined plane of the heat-dissipating body. Each electronic element has a plurality of pins bent downwards from a bottom thereof, and heat generated by the electronic elements is transmitted to external environment by matching the heat-dissipating body and the heat-dissipating fins.

Therefore, the present invention can increase heat-dissipating efficiency and decrease length of solder pin by matching the heat-dissipating substrate with the first inclined plane and the heat-dissipating fins on the heat-dissipating substrate. In addition, the electronic elements are disposed on the first inclined plane, so that the length of the pin of each electronic element of the present invention is smaller than that of the pin of each electronic element of the prior art. In other words, the length of the pin of each electronic element of the present invention can be reduced.

Moreover, the circuit substrate has a plurality of fixing grooves formed on a top surface thereof, and the substrate unit has a plurality of fixing pins disposed on a bottom surface thereof and corresponding to the fixing grooves. The fixing pins of the substrate unit are respectively embedded into the fixing grooves of the circuit substrate. Hence, when the fixing pins are respectively mated with the fixing grooves, the substrate unit can be firmly fixed on the circuit substrate without extra screw elements (such as the screws of the prior art).

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are provided solely for reference and illustration, without any intention that they be used for limiting the present invention.

### BRIEF DESCRIPTION OF THE DRAWINGS

FIG. 1 is a lateral, schematic view of the heat-dissipating module applied to PCB according to the prior art;

FIG. 2A is lateral, schematic view of the tilt-type heat-dissipating module according to the first embodiment of the present invention;

FIG. 2B is partial, perspective, schematic view of the tilt-type heat-dissipating module according to the first embodiment of the present invention;

FIG. 3 is lateral, schematic view of the tilt-type heat-dissipating module according to the second embodiment of the present invention;

FIG. 4 is lateral, schematic view of the tilt-type heat-dissipating module according to the third embodiment of the present invention;

FIG. 5 is lateral, schematic view of the tilt-type heat-dissipating module according to the fourth embodiment of the present invention;

FIG. 6 is lateral, schematic view of the tilt-type heat-dissipating module according to the fifth embodiment of the present invention;

FIG. 7 is lateral, schematic view of the tilt-type heat-dissipating module according to the sixth embodiment of the present invention;

FIG. 8 is lateral, schematic view of the tilt-type heat-dissipating module according to the seventh embodiment of the present invention;

FIG. 9 is lateral, schematic view of the tilt-type heat-dissipating module according to the eighth embodiment of the present invention;

FIG. 10 is lateral, schematic view of the tilt-type heat-dissipating module according to the ninth embodiment of the present invention;

FIG 11 is lateral, schematic view of the tilt-type heat-dissipating module according to the tenth embodiment of the present invention;

FIG. 12 is lateral, schematic view of the tilt-type heat-dissipating module according to the eleventh embodiment of the present invention; and

FIG. 13 is lateral, schematic view of the tilt-type heat-dissipating module according to the twelfth embodiment of the present invention.

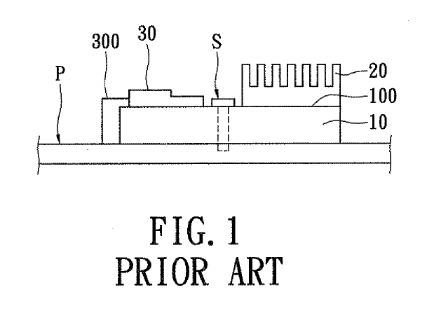

### DETAILED DESCRIPTION OF THE PREFERRED EMBODIMENTS

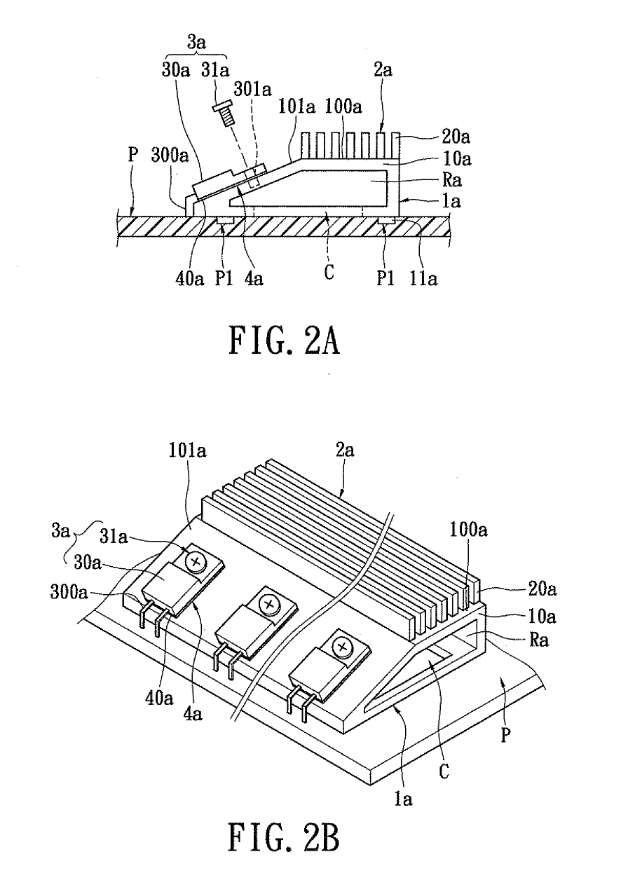

Referring to FIGS. 2A and 2B, the first embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1a, a heat-dissipating unit 2a and an electronic unit 3a.

The substrate unit 1a has a heat-dissipating body 10a disposed on the circuit substrate P. The heat-dissipating body 10a has a first inclined plane 101a formed on one part of the top surface thereof, a plane 100a formed on another part of the top surface thereof and a receiving space Ra formed therein. In addition, the heat-dissipating body 10a can add an opening C on a bottom portion of the heat-dissipating body 10a according to different requirements. Of course, the opening C also can be omitted from the heat-dissipating body 10a.

The heat-dissipating unit 2a has a plurality of heat-dissipating fins 20a connected (or integratedly connected) to the heat-dissipating body 10a. In the first embodiment, the heat-dissipating fins 20a are disposed on the plane 100a of the heat-dissipating body 10a. The heat-dissipating fins 20a can be vertically or obliquely extended upwards from the plane 100a according to different requirements. In the first embodiment, the heat-dissipating fins 20a are vertically extended upwards from the plane 100a.

The electronic unit 3a has a plurality of electronic elements 30a disposed on the first inclined plane 101a of the heat-dissipating body 10a. Each electronic element 30a has a plurality of pins 300a bent downwards from a bottom thereof in order to electrically connect to the circuit substrate P. Heat generated by the electronic elements 30a is transmitted to external environment by matching the heat-dissipating body 10a and the heat-dissipating fins 20a. In addition, each electronic element 30a has a fixing hole 301a formed on a top portion thereof, and the electronic unit 3a has a plurality of screw elements 31a corresponding to the fixing holes 301a. Each electronic element 30a is positioned on the first inclined plane 101a of the heat-dissipating body 10a by matching each screw element 31a and each fixing hole 301a.

The first embodiment further includes a heat-conducting unit 4a that has a plurality of heat-conducting elements 40a. Each heat-conducting element 40a is disposed between each electronic element 30a and the first inclined plane 101a of the heat-dissipating body 10a, and each heat-conducting element 40a can be heat-conducting paste or a heat-conducting sheet.

The circuit substrate P has a plurality of fixing grooves P1 formed on a top surface thereof, and the substrate unit 1a has a plurality of fixing pins 11a disposed on a bottom surface thereof and corresponding to the fixing grooves P1. The fixing pins 11a of the substrate unit 1a are respectively embedded into the fixing grooves P1 of the circuit substrate P. Hence, when the fixing pins 11a are respectively mated with the fixing grooves P1, the substrate unit 1a can be firmly fixed on the circuit substrate P without extra screw elements (such as the screws S of the prior art).

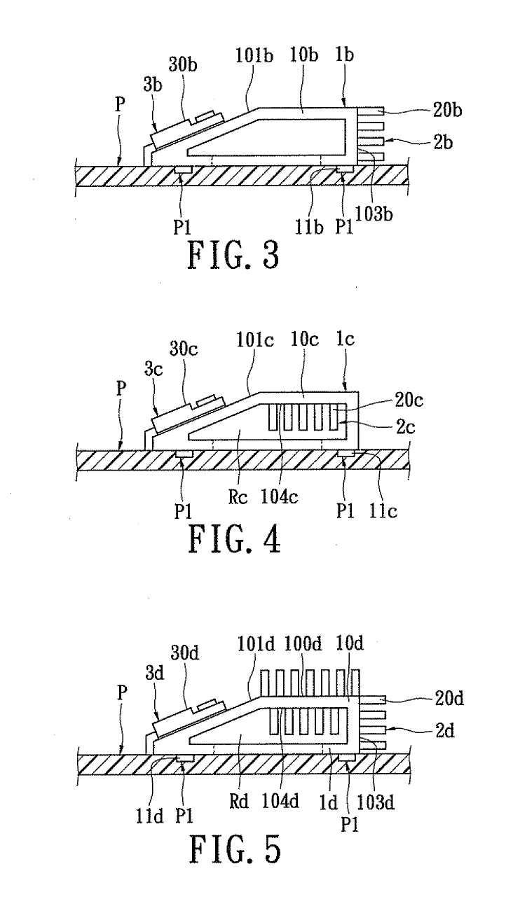

Referring to FIG. 3, the second embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1b, a heat-dissipating unit 2b and an electronic unit 3b. The substrate unit 1b has a heat-dissipating body 10b disposed on the circuit substrate P. The heat-dissipating unit 2b has a plurality of heat-dissipating fins 20b connected (or integratedly connected) to the heat-dissipating body 10b. The electronic unit 3b has a plurality of electronic elements 30b disposed on the first inclined plane 101b of the heat-dissipating body 10b. The circuit substrate P has a plurality of fixing grooves P1 formed on a top surface thereof, and the substrate unit 1b has a plurality of fixing pins 11b disposed on a bottom surface thereof and corresponding to the fixing grooves P1. The fixing pins 11b of the substrate unit 1b are respectively embedded into the fixing grooves P1 of the circuit substrate P. In addition, the difference between the second embodiment and the first embodiment is that: in the second embodiment, the heat-dissipating fins 20b are disposed on a lateral surface 103b of the heat-dissipating body 10b in order to respectively arrange the electronic elements 30b and the heat-dissipating fins 20b on two opposite lateral sides of the heat-dissipating body 10b.

Referring to FIG. 4, the third embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1c, a heat-dissipating unit 2c and an electronic unit 3c. The substrate unit 1c has a heat-dissipating body 10e disposed on the circuit substrate P. The heat-dissipating unit 2c has a plurality of heat-dissipating fins 20c connected (or integratedly connected) to the heat-dissipating body 10c. The electronic unit 3c has a plurality of electronic elements 30c disposed on the first inclined plane 101e of the heat-dissipating body 10e. The circuit substrate P has a plurality of fixing grooves P1 formed on a top surface thereof, and the substrate unit 1c has a plurality of fixing pins 11e disposed on a bottom surface thereof and corresponding to the fixing grooves P1. The fixing pins 11c of the substrate unit 1c are respectively embedded into the fixing grooves P1 of the circuit substrate P. In addition, the difference between the third embodiment and the above-mentioned embodiments is that: in the third embodiment, the heat-dissipating fins 20c are received in the receiving space Re and disposed on an inner surface 104c of the heat-dissipating body 10c.

Referring to FIG. 5, the fourth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1d, a heat-dissipating unit 2d and an electronic unit 3d. The substrate unit 1d has a heat-dissipating body 10d disposed on the circuit substrate P. The heat-dissipating unit 2d has a plurality of heat-dissipating fins 20d connected (or integratedly connected) to the heat-dissipating body 10d. The electronic unit 3d has a plurality of electronic elements 30d disposed on the first inclined plane 101d of the heat-dissipating body 10d. The circuit substrate P has a plurality of fixing grooves P1 formed on a top surface thereof, and the substrate unit 1d has a plurality of fixing pins 11d disposed on a bottom surface thereof and corresponding to the fixing grooves P1. The fixing pins 11d of the substrate unit 1d are respectively embedded into the fixing grooves P1 of the circuit substrate P. In addition, the difference between the fourth embodiment and the above-mentioned embodiments is that: in the fourth embodiment, the heat-dissipating fins 20d are disposed on a lateral surface 103d of the heat-dissipating body 10d, are received in the receiving space Rd and disposed on an inner surface 104d of the heat-dissipating body 10d and are disposed on the plane 100d of the heat-dissipating body 10d.

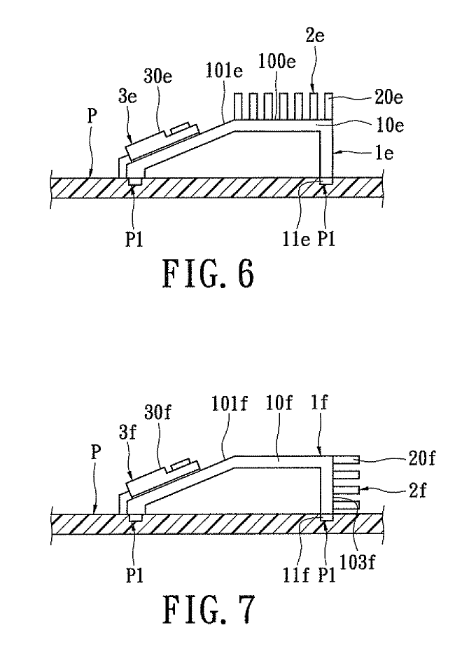

Referring to FIG. 6, the fifth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1e, a heat-dissipating unit 2e and an electronic unit 3e. The substrate unit 1e has a heat-dissipating body 10e disposed on the circuit substrate P. The heat-dissipating unit 2e has a plurality of heat-dissipating fins 20e connected (or integratedly connected) to the heat-dissipating body 10e. The electronic unit 3e has a plurality of electronic elements 30e disposed on the first inclined plane 101e of the heat-dissipating body 10e. The circuit substrate P has a plurality of fixing grooves P1 formed on a top surface thereof, and the substrate unit 1e has a plurality of fixing pins lie disposed on a bottom surface thereof and corresponding to the fixing grooves P1. The fixing pins 11e of the substrate unit 1e are respectively embedded into the fixing grooves P1 of the circuit substrate P. In addition, the difference between the fifth embodiment and the first embodiment is that: in the fifth embodiment, the heat-dissipating body 10e has a lateral surface shown as an arch shape, and the heat-dissipating fins 20e are disposed on the plane 100e of the heat-dissipating body 10e.

Referring to FIG. 7, the sixth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1f, a heat-dissipating unit 2f and an electronic unit 3f. The substrate unit 1f has a heat-dissipating body 10f disposed on the circuit substrate P. The heat-dissipating unit 2f has a plurality of heat-dissipating fins 20f connected (or integratedly connected) to the heat-dissipating body 10f. The electronic unit 3f has a plurality of electronic elements 30f disposed on the first inclined plane 101f of the heat-dissipating body 10f. The circuit substrate P has a plurality of fixing grooves P1 formed on a top surface thereof, and the substrate unit 1f has a plurality of fixing pins 11f disposed on a bottom surface thereof and corresponding to the fixing grooves P1. The fixing pins 11f of the substrate unit 1f are respectively embedded into the fixing grooves P1 of the circuit substrate P. In addition, the difference between the sixth embodiment and the fifth embodiment is that: in the sixth embodiment, the heat-dissipating fins 20f are disposed on a lateral surface 103f of the heat-dissipating body 10f in order to respectively arrange the electronic elements 30f and the heat-dissipating fins 20f on two opposite lateral sides of the heat-dissipating body 10f.

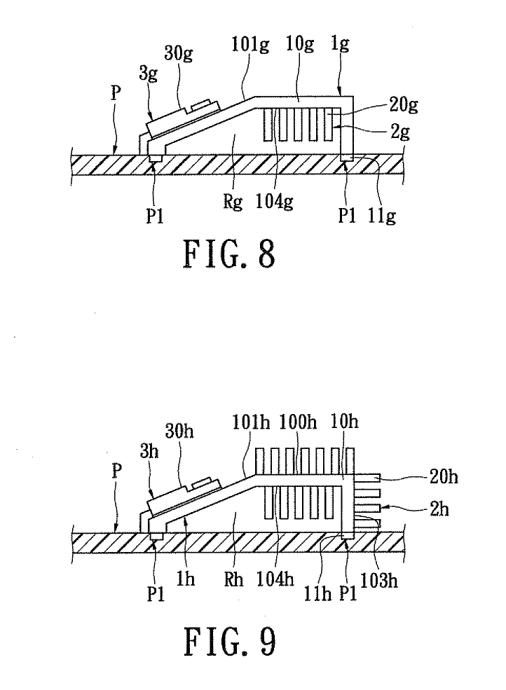

Referring to FIG. 8, the seventh embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1g, a heat-dissipating unit 2g and an electronic unit 3g. The substrate unit 1g has a heat-dissipating body 10g disposed on the circuit substrate P. The heat-dissipating unit 2g has a plurality of heat-dissipating fins 20g connected (or integratedly connected) to the heat-dissipating body 10g. The electronic unit 3g has a plurality of electronic elements 30g disposed on the first inclined plane 101g of the heat-dissipating body 10g. The circuit substrate P has a plurality of fixing grooves P1 formed on a top surface thereof, and the substrate unit 1g has a plurality of fixing pins 11g disposed on a bottom surface thereof and corresponding to the fixing grooves P1. The fixing pins 11g of the substrate unit 1g are respectively embedded into the fixing grooves P1 of the circuit substrate P. In addition, the difference between the seventh embodiment and the fifth and sixth embodiments is that: in the seventh embodiment, a receiving space Rg is formed between the heat-dissipating body 10g and the circuit substrate P, and the heat-dissipating fins 20g are received in the receiving space Rg and disposed on an inner surface 104g of the heat-dissipating body 10g.

Referring to FIG. 9, the eighth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1h, a heat-dissipating unit 2h and an electronic unit 3h. The substrate unit 1h has a heat-dissipating body 10h disposed on the circuit substrate P. The heat-dissipating unit 2h has a plurality of heat-dissipating fins 20h connected (or integratedly connected) to the heat-dissipating body 10h. The electronic unit 3h has a plurality of electronic elements 30h disposed on the first inclined plane 101h of the heat-dissipating body 10h. The circuit substrate P has a plurality of fixing grooves P1 formed on a top surface thereof, and the substrate unit 1h has a plurality of fixing pins 11h disposed on a bottom surface thereof and corresponding to the fixing grooves P1. The fixing pins 11h of the substrate unit 1h are respectively embedded into the fixing grooves P1 of the circuit substrate P. In addition, the difference between the eighth embodiment and the fifth, sixth and seventh embodiments is that: in the eighth embodiment, the heat-dissipating fins 20h are disposed on a lateral surface 103h of the heat-dissipating body 10h, are received in the receiving space Rh and disposed on an inner surface 104h of the heat-dissipating body 10h and are disposed on the plane 100h of the heat-dissipating body 10h.

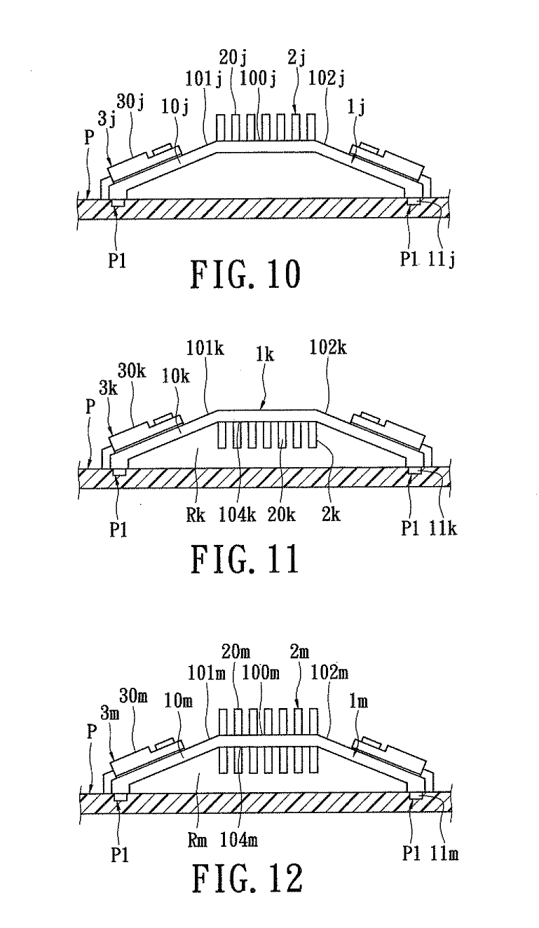

Referring to FIG. 10, the ninth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1j, a heat-dissipating unit 2j and an electronic unit 3j. The substrate unit 1j has a heat-dissipating body 10j disposed on the circuit substrate P. The heat-dissipating unit 2j has a plurality of heat-dissipating fins 20j connected (or integratedly connected) to the heat-dissipating body 10j. The electronic unit 3j has a plurality of electronic elements 30j disposed on the heat-dissipating body 10j. The circuit substrate P has a plurality of fixing grooves P1 formed on a top surface thereof, and the substrate unit 1j has a plurality of fixing pins 11j disposed on a bottom surface thereof and corresponding to the fixing grooves P1. The fixing pins 11j of the substrate unit 1j are respectively embedded into the fixing grooves P1 of the circuit substrate R In addition, the difference between the ninth embodiment and the first embodiment is that: in the ninth embodiment, the heat-dissipating body 10j has a lateral surface shown as an arch shape, and the heat-dissipating body 10j has a plane 100j, a first inclined plane 101j and a second inclined plane 102j formed on the top surface thereof. The electronic elements 30j are disposed on the first inclined plane 101j and a second inclined plane 102j, and the heat-dissipating fins 20j are disposed on the plane 100j.

Referring to FIG. 11, the tenth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1k, a heat-dissipating unit 2k and an electronic unit 3k. The substrate unit 1k has a heat-dissipating body 10k disposed on the circuit substrate P. The heat-dissipating unit 2k has a plurality of heat-dissipating fins 20k connected (or integratedly connected) to the heat-dissipating body 10k. The electronic unit 3k has a plurality of electronic elements 30k disposed on the first inclined plane 101k and a second inclined plane 102k of the heat-dissipating body 10k. The circuit substrate P has a plurality of fixing grooves P1 formed on a top surface thereof, and the substrate unit 1k has a plurality of fixing pins 11k disposed on a bottom surface thereof and corresponding to the fixing grooves P1. The fixing pins 11k of the substrate unit 1k are respectively embedded into the fixing grooves P1 of the circuit substrate P. In addition, the difference between the tenth embodiment and the ninth embodiment is that: in the tenth embodiment, a receiving space Rk is formed between the heat-dissipating body 10k and the circuit substrate P, and the heat-dissipating fins 20k are received in the receiving space Rk and disposed on an inner surface 104k of the heat-dissipating body 10k.

Referring to FIG. 12, the eleventh embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1m, a heat-dissipating unit 2m and an electronic unit 3m. The substrate unit 1m has a heat-dissipating body 10m disposed on the circuit substrate P. The heat-dissipating unit 2m has a plurality of heat-dissipating fins 20m connected (or integratedly connected) to the heat-dissipating body 10m. The electronic unit 3m has a plurality of electronic elements 30m disposed on the first inclined plane 101m and a second inclined plane 102m of the heat-dissipating body 10m. The circuit substrate P has a plurality of fixing grooves P1 formed on a top surface thereof, and the substrate unit 1m has a plurality of fixing pins 11m disposed on a bottom surface thereof and corresponding to the fixing grooves P1. The fixing pins 11m of the substrate unit 1m are respectively embedded into the fixing grooves P1 of the circuit substrate P. In addition, the difference between the eleventh embodiment and the ninth and tenth embodiments is that: in the eleventh embodiment, and the heat-dissipating fins 20m are disposed on the plane 100m of the heat-dissipating body 10m and are received in the receiving space Rm and disposed on an inner surface 104m of the heat-dissipating body 10m.

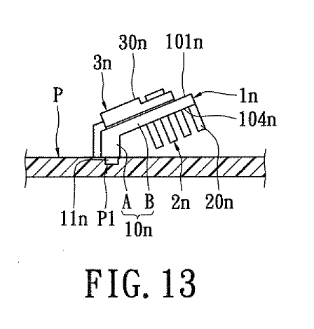

Referring to FIG. 13, the twelfth embodiment of the present invention provides a tilt-type heat-dissipating module for increasing heat-dissipating efficiency and decreasing length of solder pin. The tilt-type heat-dissipating module is disposed on a circuit substrate P, and the tilt-type heat-dissipating module includes a substrate unit 1n, a heat-dissipating unit 2n and an electronic unit 3n. The substrate unit 1n has a heat-dissipating body 10n disposed on the circuit substrate P. The heat-dissipating unit 2n has a plurality of heat-dissipating fins 20n connected (or integratedly connected) to the heat-dissipating body 10n. The electronic unit 3n has a plurality of electronic elements 30n disposed on the first inclined plane 101n of the heat-dissipating body 10n. The circuit substrate P has a plurality of fixing grooves P1 formed on a top surface thereof, and the substrate unit in has a plurality of fixing pins 11n disposed on a bottom surface thereof and corresponding to the fixing grooves P1. The fixing pins 11n of the substrate unit 1n are respectively embedded into the fixing grooves P1 of the circuit substrate P. In addition, the difference between the twelfth embodiment and the above-mentioned embodiments is that: in the twelfth embodiment, the heat-dissipating body 10n is composed of an extending portion A being positioned on the circuit substrate P and an inclined portion B being obliquely extended upwards from the extending portion A and suspended, the first inclined plane 101n is formed on a top surface of the inclined portion B, and the heat-dissipating body 10n is disposed on a bottom surface 104n of the inclined portion B.

In conclusion, the present invention can increase heat-dissipating efficiency and decrease length of solder pin by matching the heat-dissipating substrate with the first inclined plane and the heat-dissipating fins on the heat-dissipating substrate. In addition, the electronic elements are disposed on the first inclined plane, so that the length of the pin of each electronic element of the present invention is smaller than that of the pin of each electronic element of the prior art. In other words, the length of the pin of each electronic element of the present invention can be reduced.

Moreover, the circuit substrate has a plurality of fixing grooves formed on a top surface thereof, and the substrate unit has a plurality of fixing pins disposed on a bottom surface thereof and corresponding to the fixing grooves. The fixing pins of the substrate unit are respectively embedded into the fixing grooves of the circuit substrate. Hence, when the fixing pins are respectively mated with the fixing grooves, the substrate unit can be firmly fixed on the circuit substrate without extra screw elements (such as the screws of the prior art).

The above-mentioned descriptions merely represent solely the preferred embodiments of the present invention, without any intention or ability to limit the scope of the present invention which is fully described only within the following claims. Various equivalent changes, alterations or modifications based on the claims of present invention are all, consequently, viewed as being embraced by the scope of the present invention.

What is claimed is:

1. A tilt-type heat-dissipating module for increasing heat-dissipating efficiency and decreasing length of solder pin disposed on a circuit substrate, the tilt-type heat-dissipating module comprising:
a substrate unit having a heat-dissipating body disposed on the circuit substrate, wherein one part of a top surface of the heat-dissipating body is a first inclined plane;
a heat-dissipating unit having a plurality of heat-dissipating fins connected to the heat-dissipating body; and
an electronic unit having a plurality of electronic elements disposed on the first inclined plane of the heat-dissipating body, wherein each electronic element has a plurality of pins bent downwards from a bottom thereof in order to electrically connect to the circuit substrate, and heat generated by the electronic elements is transmitted to the external environment by matching the heat-dissipating body and the heat-dissipating fins.

2. The tilt-type heat-dissipating module according to claim 1, wherein the heat-dissipating body has a receiving space formed therein, another part of the top surface of the heat-dissipating body is a plane, and the heat-dissipating fins are disposed on the plane of the heat-dissipating body.

3. The tilt-type heat-dissipating module according to claim 1, wherein the heat-dissipating body has a receiving space formed therein, and the heat-dissipating fins are disposed on a lateral surface of the heat-dissipating body in order to respectively arrange the electronic elements and the heat-dissipating fins on two opposite lateral sides of the heat-dissipating body.

4. The tilt-type heat-dissipating module according to claim 1, wherein the heat-dissipating body has a receiving space formed therein, and the heat-dissipating fins are received in the receiving space and disposed on an inner surface of the heat-dissipating body.

5. The tilt-type heat-dissipating module according to claim 1, wherein the heat-dissipating body has a receiving space formed therein, another part of the top surface of the heat-dissipating body is a plane, and the heat-dissipating fins are disposed on a lateral surface of the heat-dissipating body, are received in the receiving space and disposed on an inner surface of the heat-dissipating body and are disposed on the plane of the heat-dissipating body.

6. The tilt-type heat-dissipating module according to claim 1, wherein the heat-dissipating body has a lateral surface shown as an arch shape, another part of the top surface of the heat-dissipating body is a plane, and the heat-dissipating fins are disposed on the plane of the heat-dissipating body.

7. The tilt-type heat-dissipating module according to claim 1, wherein the heat-dissipating body has a lateral surface shown as an arch shape, and the heat-dissipating fins are disposed on a lateral surface of the heat-dissipating body in order to respectively arrange the electronic elements and the heat-dissipating fins on two opposite lateral sides of the heat-dissipating body.

8. The tilt-type heat-dissipating module according to claim 1, wherein the heat-dissipating body has a lateral surface shown as an arch shape, a receiving space is formed between the heat-dissipating body and the circuit substrate, and the heat-dissipating fins are received in the receiving space and disposed on an inner surface of the heat-dissipating body.

9. The tilt-type heat-dissipating module according to claim 1, wherein the heat-dissipating body has a lateral surface shown as an arch shape, another part of the top surface of the heat-dissipating body is a plane, a receiving space is formed between the heat-dissipating body and the circuit substrate, and the heat-dissipating fins are disposed on a lateral surface of the heat-dissipating body, are received in the receiving space and disposed on an inner surface of the heat-dissipating body and are disposed on the plane of the heat-dissipating body.

10. The tilt-type heat-dissipating module according to claim 1, wherein the heat-dissipating body has a lateral surface shown as an arch shape, another part of the top surface of the heat-dissipating body is a plane and a second inclined plane, one part of the electronic elements are disposed on the second inclined plane of the heat-dissipating body, and the heat-dissipating fins are disposed on the plane of the heat-dissipating body.

11. The tilt-type heat-dissipating module according to claim 1, wherein the heat-dissipating body has a lateral surface shown as an arch shape, another part of the top surface of the heat-dissipating body is a plane and a second inclined plane, one part of the electronic elements are disposed on the second inclined plane of the heat-dissipating body, a receiving space is formed between the heat-dissipating body and the circuit substrate, and the heat-dissipating fins are received in the receiving space and disposed on an inner surface of the heat-dissipating body.

12. The tilt-type heat-dissipating module according to claim 1, wherein the heat-dissipating body has a lateral surface shown as an arch shape, another part of the top surface of the heat-dissipating body is a plane and a second inclined plane, one part of the electronic elements are disposed on the second inclined plane of the heat-dissipating body, a receiving space is formed between the heat-dissipating body and the circuit substrate, and the heat-dissipating fins are disposed on the plane of the heat-dissipating body and are received in the receiving space and disposed on an inner surface of the heat-dissipating body.

13. The tilt-type heat-dissipating module according to claim 1, wherein the heat-dissipating body is composed of an extending portion being positioned on the circuit substrate and an inclined portion being obliquely extended upwards from the extending portion and suspended, the first inclined plane is formed on a top surface of the inclined portion, and the heat-dissipating body is disposed on a bottom surface of the inclined portion.

14. The tilt-type heat-dissipating module according to claim 1, further comprising: a heat-conducting unit that has a plurality of heat-conducting elements, wherein each heat-conducting element is disposed between each electronic element and the first inclined plane of the heat-dissipating body, and each heat-conducting element is heat-conducting paste or a heat-conducting sheet.

15. The tilt-type heat-dissipating module according to claim 1, wherein the heat-dissipating body has an opening formed on a bottom portion thereof, the circuit substrate has a plurality of fixing grooves formed on a top surface thereof, the substrate unit has a plurality of fixing pins disposed on a bottom surface thereof and corresponding to the fixing grooves, and the fixing pins of the substrate unit are respectively embedded into the fixing grooves of the circuit substrate.

16. The tilt-type heat-dissipating module according to claim 1, wherein each electronic element has a fixing hole formed on a top portion thereof, the electronic unit has a plurality of screw elements corresponding to the fixing holes, and each electronic element is positioned on the first inclined plane of the heat-dissipating body by matching each screw element and each fixing hole.

17. A tilt-type heat-dissipating module for increasing heat-dissipating efficiency and decreasing length of solder pin, comprising:
a substrate unit having a hollow heat-dissipating body, wherein the heat-dissipating body has a receiving space formed therein, an inclined plane formed on one part of a top surface thereof and a plane formed on another part of the top surface thereof;
a heat-dissipating unit having a plurality of heat-dissipating fins disposed on the plane of the heat-dissipating body; and
an electronic unit having a plurality of electronic elements disposed on the inclined plane of the heat-dissipating body, wherein each electronic element has a plurality of pins bent downwards from a bottom thereof, and heat generated by the electronic elements is transmitted to external environment by matching the heat-dissipating body and the heat-dissipating fins.

18. The tilt-type heat-dissipating module according to claim 17, further comprising: a heat-conducting unit that has a plurality of heat-conducting elements, wherein each heat-conducting element is disposed between each electronic element and the inclined plane of the heat-dissipating body, and each heat-conducting element is heat-conducting paste or a heat-conducting sheet.

19. The tilt-type heat-dissipating module according to claim 17, wherein the heat-dissipating body has an opening formed on a bottom portion thereof, the circuit substrate has a plurality of fixing grooves formed on a top surface thereof, the substrate unit has a plurality of fixing pins disposed on a bottom surface thereof and corresponding to the fixing grooves, and the fixing pins of the substrate unit are respectively embedded into the fixing grooves of the circuit substrate.

20. The tilt-type heat-dissipating module according to claim 17, wherein each electronic element has a fixing hole formed on a top portion thereof, the electronic unit has a plurality of screw elements corresponding to the fixing holes, and each electronic element is positioned on the inclined plane of the heat-dissipating body by matching each screw element and each fixing hole.
